(19) United States
(12) Patent Application Publication
(10) Pub. No.: US 2018/0040601 A1
(43) Pub. Date: Feb. 8, 2018

(54) SEMICONDUCTOR DEVICE AND COMPOSITE SEMICONDUCTOR DEVICE

(71) Applicant: SHARP KABUSHIKI KAISHA, Sakai City, Osaka (JP)

(72) Inventor: Seiichiro KIHARA, Sakai City, Osaka (JP)

(73) Assignee: SHARP KABUSHIKI KAISHA, Sakai City, Osaka (JP)

(21) Appl. No.: 15/555,334

(22) PCT Filed: Feb. 16, 2016
(86) PCT No.: PCT/JP2016/054482

§ 371 Date: Sep. 1, 2017

(30) Foreign Application Priority Data
Apr. 15, 2015 (JP) 2015-083753

(51) Int. Cl. H01L 27/02; H01L 27/24; H01L 27/06

(52) U.S. Cl. CPC H01L 27/0207; H01L 27/0629; H01L 27/2436

(57) ABSTRACT

Provided is a lateral field effect transistor in which response performance is improved. In a lateral field effect transistor, a block is arranged closer to a gate terminal than a Zener diode.

### TECHNICAL FIELD

The present invention relates to a semiconductor device including a plurality of normally-off field effect transistors or a plurality of normally-on field effect transistors, and a composite semiconductor device including a normally-on field effect transistor and a plurality of normally-off field effect transistors.

### BACKGROUND ART

A Si (silicon)-based field effect transistor mainly used in a current semiconductor device is a normally-off transistor. The normally-off field effect transistor is a transistor that is made conductive when a positive voltage is applied across a gate electrode (G) and a source electrode (S) and made non-conductive when a positive voltage is not applied across the gate electrode (G) and the source electrode (S). As one of the methods for realizing the normally-off field effect transistor, there is a lateral double-diffused MOS field effect transistor (LDMOSFET). The lateral double-diffused MOS field effect transistor has characteristics that the source electrode (S) and the drain electrode (D) are formed on the same surface of a semiconductor substrate and that an electrode on a back surface of the semiconductor is allowed to be connected by a trench penetrating the semiconductor from the source electrode (S).

Meanwhile, researches of an III-N-based field effect transistor such as a GaN-based transistor, which is a normally-on transistor, have been conducted for practical use as the III-N-based field effect transistor has characteristics such as a high withstand voltage, low loss, high-speed switching, and an operation at high temperature. The normally-on field effect transistor has a negative threshold voltage, and is made non-conductive when voltage between a gate electrode (G) and a source electrode (S) is lower than the threshold voltage and made conductive when voltage between the gate electrode (G) and the source electrode (S) is higher than the threshold voltage. When such a normally-on field effect transistor is used in a semiconductor device, various problems such that a conventional gate drive circuit is not able to be used may arise.

Then, PTL 1 described below proposes a normally-off composite semiconductor device that is formed by connecting a normally-on field effect transistor and normally-off field effect transistors to each other in series. Further, PTL 2 described below proposes a method of connecting a Zener diode between a drain electrode (D) and a source electrode (S) of a normally-off field effect transistor so as to restrict voltage between the drain electrode (D) and the source electrode (S) to voltage not higher than a withstand voltage of the normally-off field effect transistor in order to prevent the normally-off field effect transistor from breaking down due to the voltage between the drain electrode (D) and the source electrode (S) of the normally-off field effect transistor becoming high.

### CITATION LIST

### Patent Literature

PTL 1: Japanese Unexamined Patent Application Publication No. 2006-158185 (published on Jun. 15, 2006)

PTL 2: Japanese Unexamined Patent Application Publication No. 2006-324839 (published on Nov. 30, 2006)

### SUMMARY OF INVENTION

### Technical Problem

However, the normally-off field effect transistor (semiconductor device) included in the conventional normally-off composite semiconductor device described above is constituted in many cases by a collection of small field effect transistors called fingers. A gate electrode (G) of each of the fingers is connected by metal wiring from a gate terminal of the normally-off field effect transistor. Thus, a gate signal transmitted to a gate electrode of a finger arranged on a side opposite the side of the gate terminal of the normally-off field effect transistor is significantly delayed as compared to a gate signal transmitted to a gate electrode of a finger arranged near the gate terminal of the normally-off field effect transistor. This causes deterioration in response performance of the composite semiconductor device.

On the other hand, it is also considered that the normally-on field effect transistor (semiconductor device) is constituted by a collection of small field effect transistors called fingers, and the aforementioned problem may arise in such a case as well. In particular, an III-N based normally-on field effect transistor, such as a GaN-based field effect transistor, or a normally-on field effect transistor using SiC or the like has a property of having a high withstand voltage and a low on-resistance and operating at high speed as compared to a Si-based normally-off field effect transistor, and when the normally-on field effect transistor is not sufficient in response performance, high-speed response performance thereof is restricted.

An object of the invention is to provide a semiconductor device in which response performance is improved.

### Solution to Problem

In order to solve the aforementioned problems, a semiconductor device of the invention includes a plurality of normally-off or normally-on field effect transistors, a gate terminal, a drain terminal, a source terminal, each of the field effect transistors having a gate electrode connected to the gate terminal, a drain electrode connected to the drain terminal, and a source electrode connected to the source terminal, and a Zener diode that has an anode electrode connected to the source terminal and a cathode electrode connected to the drain terminal. The field effect transistors are each arranged to have a distance from the gate terminal increasing in order and form a block. The block is arranged closer to the gate terminal than the Zener diode.

According to the aforementioned configuration, the plurality of field effect transistors that are greatly influenced by wiring resistance are arranged closer to the gate terminal than the Zener diode. Thus, it is possible to suppress delay of transmission, to the gate electrode of each of the field effect transistors, of a signal supplied from the gate terminal and realize a semiconductor device in which response performance is improved.

### Advantageous Effects of Invention

According to an aspect of the invention, it is possible to realize a semiconductor device in which response performance is improved.

### BRIEF DESCRIPTION OF DRAWINGS

FIG. 1 is a circuit diagram illustrating a schematic configuration of a normally-off lateral field effect transistor according to an embodiment of the invention.

FIG. 2 is a circuit diagram illustrating a schematic configuration of an evaluation circuit for evaluating an operation of the lateral field effect transistor illustrated in FIG. 1.

FIG. 3 illustrates operation timing of the lateral field effect transistor illustrated in FIG. 1.

FIG. 4 illustrates the lateral field effect transistor illustrated in FIG. 1 when viewed from a direction of a surface on which a gate terminal is formed.

FIG. 5 is a circuit diagram illustrating a schematic configuration of a normally-on lateral field effect transistor according to another embodiment of the invention.

FIG. 6 illustrates operation timing of the lateral field effect transistor illustrated in FIG. 5.

FIG. 7 is a circuit diagram illustrating a schematic configuration of a composite semiconductor device according to still another embodiment of the invention, which includes the normally-off lateral field effect transistor illustrated in FIG. 1 and a normally-on field effect transistor.

FIG. 8 illustrates a schematic configuration of a composite semiconductor device obtained by performing package processing for the composite semiconductor device illustrated in FIG. 7.

### DESCRIPTION OF EMBODIMENTS

Hereinafter, embodiments of the invention will be specifically described with reference to drawings. Note that, dimensions, materials, shapes, relative arrangement, and processing methods etc. of components described in the embodiments merely exemplify an embodiment, and should not be construed as limiting the scope of the invention only to them. Further, the drawings are schematically represented and ratios between dimensions and shapes are different from those in actual cases.

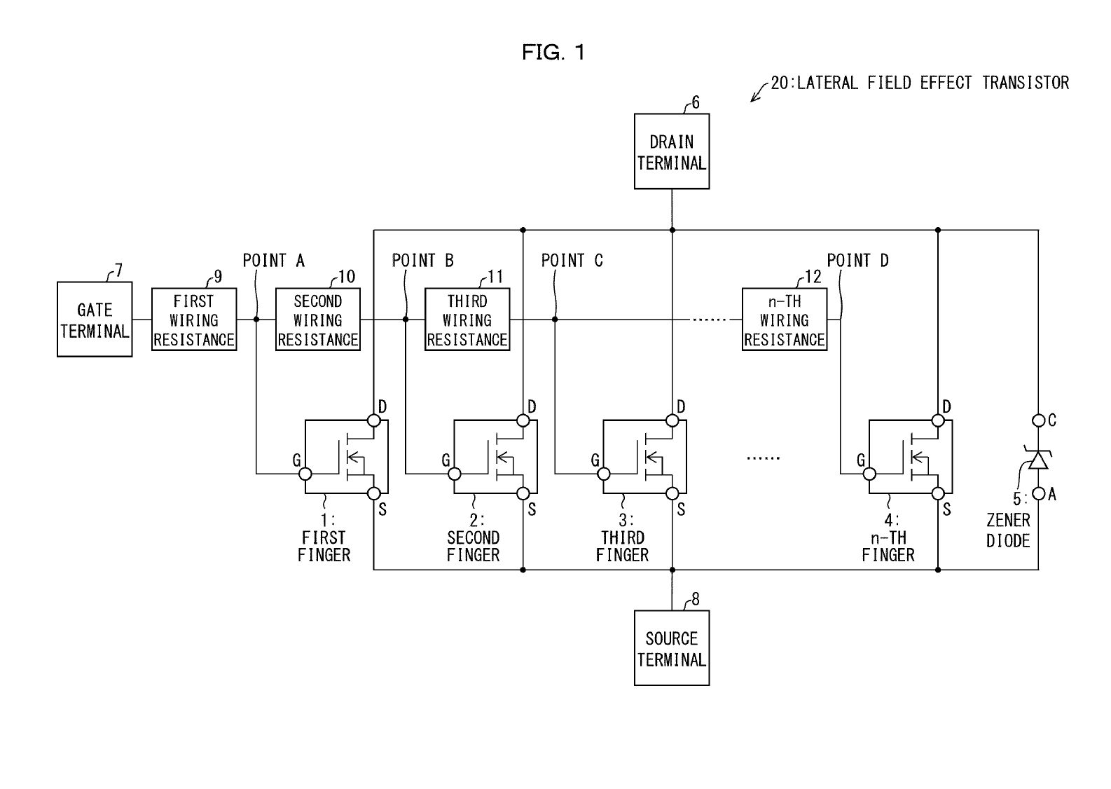

The embodiments of the invention will be described as follows with reference to FIGS. 1 to 8.

### Embodiment 1

An embodiment of the invention will be described below with reference to FIGS. 1 to 4.

FIG. 1 is a circuit diagram illustrating a schematic configuration of a normally-off lateral field effect transistor 20.

As illustrated in the figure, the normally-off lateral field effect transistor 20 (semiconductor device) includes first to n-th fingers 1, 2, 3 . . . , and 4 that are n (n is an integer equal to or greater than 2) small field effect transistors, a Zener diode 5, a drain terminal 6, a gate terminal 7, a source terminal 8, and wiring resistances (a first wiring resistance 9, a second wiring resistance 10, a third wiring resistance 11 . . . , and an n-th wiring resistance 12).

### Finger

Since the lateral field effect transistor 20 is a normally-off transistor, each of the first to n-th fingers 1, 2, 3 . . . , and 4 is a normally-off small field effect transistor and includes a gate electrode (G), a drain electrode (D), and a source electrode (S). The lateral field effect transistor 20 includes a collection (block) of small field effect transistors called fingers. Note that, the number n of the fingers is thousands to tens of thousands in accordance with current capacity and a collection (block) of thousands to tens of thousands fingers is generally formed.

Note that, the source electrode (S) of each of the first to n-th fingers 1, 2, 3 . . . , and 4 needs to be connected to the source terminal 8 that is arranged on a back surface as described later. Thus, each of the first to n-th fingers 1, 2, 3 . . . , and 4 preferably has a structure of a lateral double-diffused MOS field effect transistor. This is because the lateral double-diffused MOS field effect transistor has characteristics that a source electrode and a drain electrode are formed on the same surface of a semiconductor substrate and further allows connection to an electrode on a back surface of the semiconductor by a trench penetrating the semiconductor from the source electrode.

### Gate Terminal of Normally-Off Lateral Field Effect Transistor

The gate terminal 7 of the normally-off lateral field effect transistor 20 is connected to the gate electrodes (G) of the first to n-th fingers 1, 2, 3 . . . , and 4. The first wiring resistance 9 is present in wiring between the gate terminal 7 and the gate electrode (G) of the first finger 1. The first wiring resistance 9 and the second wiring resistance 10 are present in series in wiring between the gate terminal 7 and the gate electrode (G) of the second finger 2. The first wiring resistance 9, the second wiring resistance 10, and the third wiring resistance 11 are present in series in wiring between the gate terminal 7 and the gate electrode (G) of the third finger 3. The first to n-th wiring resistances (the first wiring resistance 9, the second wiring resistance 10, the third wiring resistance 11, and the n-th wiring resistance 12), that is n wiring resistances, are present in series in wiring between the gate terminal 7 and the gate electrode (G) of the n-th finger 4.

### Drain Terminal and Source Terminal of Normally-Off Lateral Field Effect Transistor

The drain electrodes (D) of the first to n-th fingers 1, 2, 3 . . . , and 4 are connected to the drain terminal 6 of the normally-off lateral field effect transistor 20. On the other hand, the source electrodes (S) of the first to n-th fingers 1, 2, 3 . . . , and 4 are connected to the source terminal 8 of the normally-off lateral field effect transistor 20.

### Zener Diode

Voltage larger than or equal to a withstand voltage of the normally-off lateral field effect transistor 20 may be applied thereto, and in order to prevent breakdown in such a case, the normally-off lateral field effect transistor 20 includes the Zener diode 5. The Zener diode 5 has an anode electrode (A) connected to the source terminal 8 and a cathode electrode (C) connected to the drain terminal 6. Since the Zener diode 5 receives small influence of the wiring resistances described above, the Zener diode 5 is arranged farther from the gate terminal 7 than the first to n-th fingers 1, 2, 3 . . . , and 4. That is, the first to n-th fingers 1, 2, 3 . . . , and 4 are arranged closer to the gate terminal 7 than the Zener diode 5.

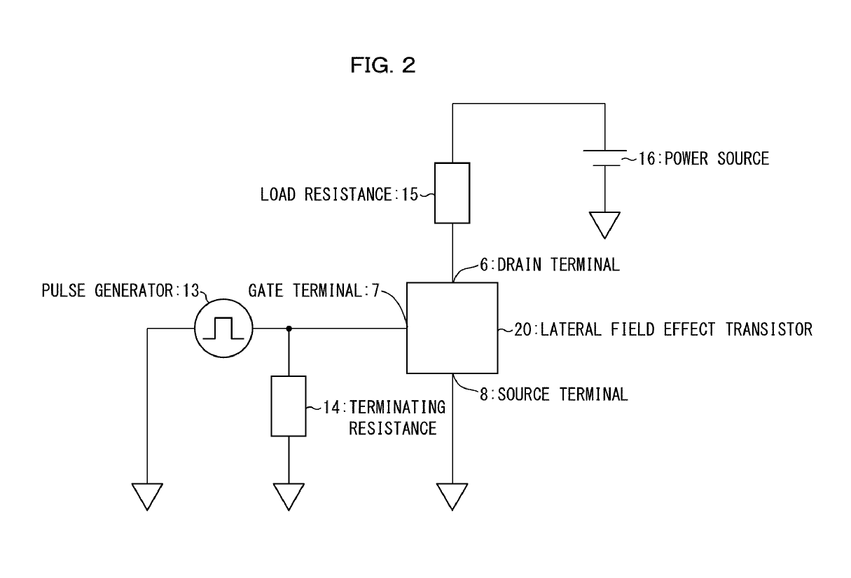

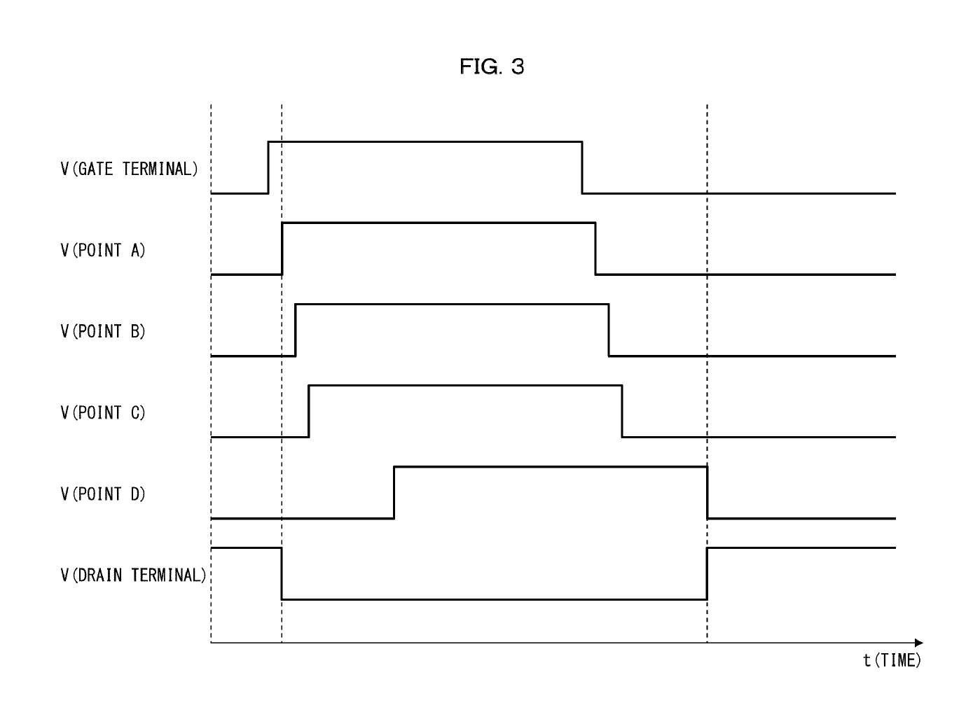

An operation of the normally-off lateral field effect transistor 20 will be described below with reference to FIGS. 2 and 3.

### Evaluation Circuit

FIG. 2 is a circuit diagram illustrating a schematic configuration of an evaluation circuit for evaluating an operation of the normally-off lateral field effect transistor 20 illustrated in FIG. 1.

As illustrated in the figure, the evaluation circuit includes the lateral field effect transistor 20, a pulse generator 13, a terminating resistance 14, a load resistance 15, and a power source 16. One end of the pulse generator 13 is grounded, and the other end of the pulse generator 13 is connected to one end of the terminating resistance 14, the other end of which is grounded, and connected to the gate terminal 7 of the lateral field effect transistor 20. The drain terminal 6 of the lateral field effect transistor 20 is connected to one end of the load resistance 15 and the other end of the load resistance 15 is connected to a positive terminal of the power source 16 whose minus terminal is grounded. The source terminal 8 of the lateral field effect transistor 20 is grounded.

### About Operation of Normally-Off Lateral Field Effect Transistor

FIG. 3 illustrates operation timing of the lateral field effect transistor 20 illustrated in FIG. 1.

Each voltage illustrated in FIG. 3 indicates voltage change of each portion of the lateral field effect transistor 20 illustrated in FIG. 1. The voltage of the gate terminal 7 of the lateral field effect transistor 20 is denoted by V (gate terminal), the voltage of a point A in FIG. 1 is denoted by V (point A), the voltage of a point B in FIG. 1 is denoted by V (point B), the voltage of a point C in FIG. 1 is denoted by V (point C), the voltage of a point D in FIG. 1 is denoted by V (point D), and the voltage of the drain terminal 6 of the lateral field effect transistor 20 is denoted by V (drain terminal).

As illustrated in V (gate terminal), when voltage (high level) equal to or greater than a gate voltage at which the lateral field effect transistor 20 is turned on is input to the gate terminal 7, first, voltage (high level) equal to or greater than a gate voltage at which the first finger 1 nearest to the gate terminal 7 is turned on is input to the gate electrode (G) of the finger 1 with delay due to influence of the first wiring resistance 9 as illustrated in V (point A). When the first finger 1 is turned on, current flows through the lateral field effect transistor 20, so that the current appears in V (drain terminal) and V (drain terminal) is changed from a high level to a low level at timing when the first finger 1 is turned on. Then, with more delay due to influence of the second wiring resistance 10 being added as illustrated in V (point B), voltage (high level) equal to or greater than a gate voltage at which the second finger 2 is turned on is input to the gate electrode (G) of the second finger 2. When the second finger 2 is turned on, current flows through the lateral field effect transistor 20, but since V (drain terminal) has been already changed from the high level to the low level, at timing when the second finger 2 is turned on, there is no change in the voltage of V (drain terminal) and the low level is kept. Then, with more delay due to influence of the second wiring resistance 10 and the third wiring resistance 11 being added as illustrated in V (point C), voltage (high level) equal to or greater than a gate voltage at which the third finger 3 is turned on is input to the gate electrode (G) of the third finger 3. When the third finger 3 is turned on, current flows through the lateral field effect transistor 20, but since V (drain terminal) has been already changed from the high level to the low level, at timing when the third finger 3 is turned on, there is no change in the voltage of V (drain terminal) and the low level is kept. Finally, with more delay due to influence of the second to n-th wiring resistances (10, 11 . . . , and 12) being added as illustrated in V (point D), voltage (high level) equal to or greater than a gate voltage at which the n-th finger 4 is turned on is input to the gate electrode (G) of the n-th finger 4. When the n-th finger 4 is turned on, current flows through the lateral field effect transistor 20, but since V (drain terminal) has been already changed from the high level to the low level, at timing when the n-th finger 4 is turned on, there is no change in the voltage of V (drain terminal) and the low level is kept.

When voltage (high level) equal to or greater than a gate voltage at which the lateral field effect transistor 20 is turned on is input to the gate terminal 7 for a certain time period and the voltage level is then returned to the low level as illustrated in V (gate terminal), the first finger 1 is turned off with delay due to influence of the first wiring resistance 9 as illustrated in V (point A), but the change of the current does not appear in V (drain terminal) because the other fingers 2, 3 . . . , and 4 are on. With a lapse of time, the second finger 2 and the third finger 3 are successively turned off with delay due to influence of the wiring resistance in the same manner, and V (drain terminal) keeps the low level until the n-th finger 4 is turned off and V (drain terminal) is brought into the high level at timing when the n-th finger 4 is turned off.

As illustrated in the figure, in the lateral field effect transistor 20, an OFF delay time (time from timing when V (gate terminal) is brought into the low level to timing when V (drain terminal) is brought into the high level) tends to be longer than an ON delay time (time from timing when V (gate terminal) is brought into the high level to timing when V (drain terminal) is brought into the low level) due to influence of the wiring resistance.

In a general lateral field effect transistor including thousands to tens of thousands fingers, reduction in wiring resistance is required to reduce the OFF delay time and it is necessary to make countermeasures so that current concentration on a specific finger having a markedly high wiring resistance does not cause breakdown of the specific finger.

Thus, the lateral field effect transistor 20 of the present embodiment has a configuration in which the first to n-th fingers 1, 2, 3 . . . , and 4 are arranged closer to the gate terminal 7 than the Zener diode 5. With the configuration, it is possible to suppress an increase in the wiring resistances that are present in series in wiring between the gate terminal 7 and the gate electrode (G) of the n-th finger 4 farthest from the gate terminal 7 and a finger having a markedly high wiring resistance is not generated because of arrangement of the first to n-th fingers 1, 2, 3 . . . , and 4. As a result, in the lateral field effect transistor 20, the OFF delay time is able to be reduced and breakdown of a specific finger is less likely to be generated compared to a conventional one.

### Arrangement of Lateral Field Effect Transistor

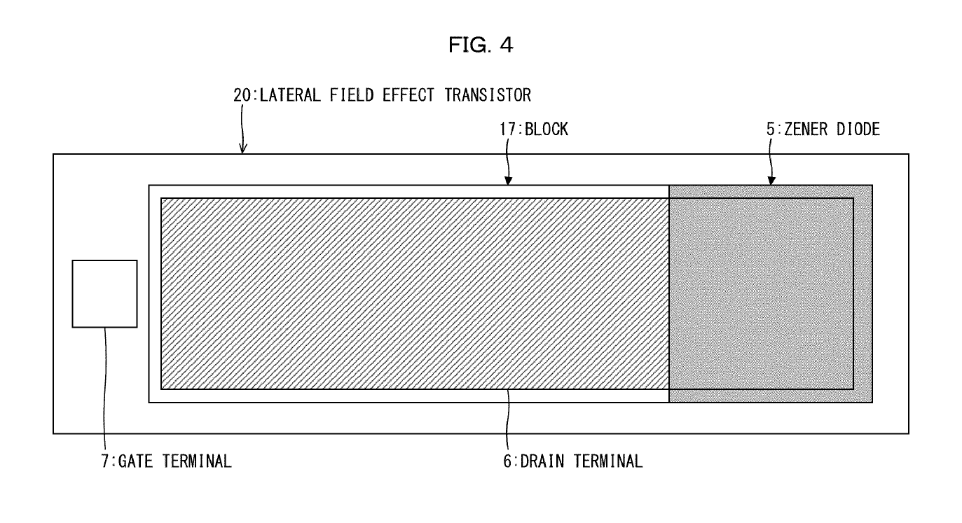

FIG. 4 illustrates the lateral field effect transistor 20 illustrated in FIG. 1 when viewed from a direction of a surface on which the gate terminal 7 is formed.

As illustrated in the figure, the lateral field effect transistor 20 includes the collection of the first to n-th fingers 1, 2, 3 . . . , and 4, that is, a block 17 in which the first to n-th fingers 1, 2, 3 . . . , and 4 are arranged, the Zener diode 5, the drain terminal 6, the gate terminal 7, and a source terminal (not-illustrated) that is arranged on the back surface.

In the block 17, the first to n-th fingers 1, 2, 3 . . . , and 4 are each arranged to have a distance from the gate terminal 7 increasing in order.

Since the Zener diode 5 receives small influence of the wiring resistances, the Zener diode 5 is arranged farthest from the gate terminal 7. With such arrangement, the first to n-th fingers 1, 2, 3 . . . , and 4 that are greatly influenced by the wiring resistances are able to be arranged closer to the gate terminal 7 as much as possible and the OFF delay time is able to be reduced.

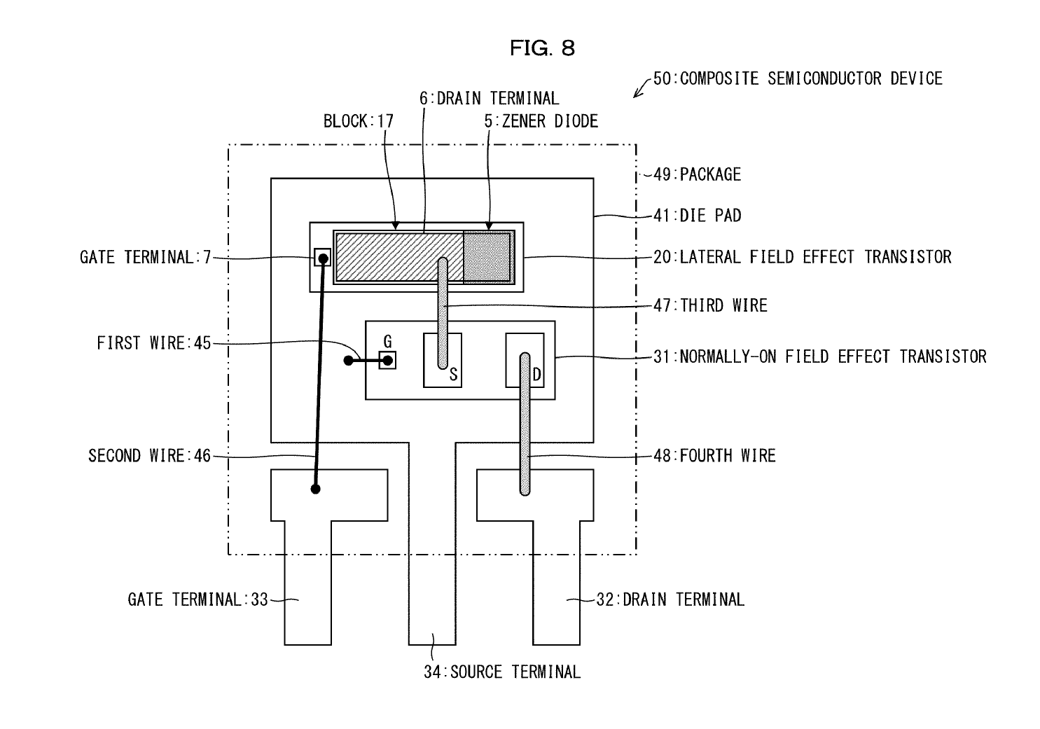

The lateral field effect transistor 20 of the present embodiment is a normally-off transistor, and thus conforms to pin assignment of a package of a general Si-based field effect transistor in many cases. In such a packaged semiconductor device, terminals are arrayed in order of a gate terminal, a drain terminal, and a source terminal, and the gate terminal on a chip of the lateral field effect transistor is also wired to one end of a short side of the chip in many cases. Also in such a case, the OFF delay time is able to be reduced by arranging a Zener diode in an end opposite the short side of the chip at which the gate terminal is present (refer to FIG. 8 described below).

Note that, though description has been given by taking the lateral field effect transistor as an example in the present embodiment, the invention is able to be applied not only to the lateral field effect transistor but also to field effect transistors in general. Since both normally-off and normally-on field effect transistors serving as power devices (in which a withstand voltage is high and current is large) have a finger structure, the invention is able to be applied not only to a normally-off lateral field effect transistor but also to a normally-on lateral field effect transistor.

### Embodiment 2

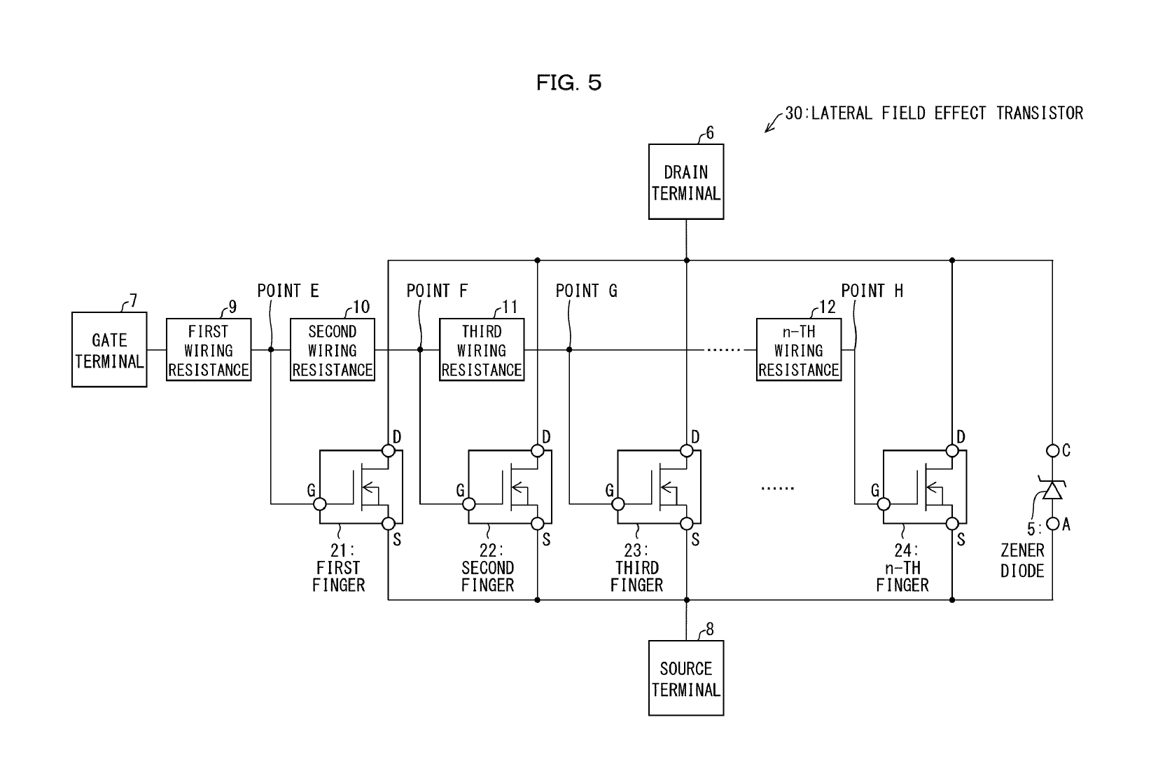

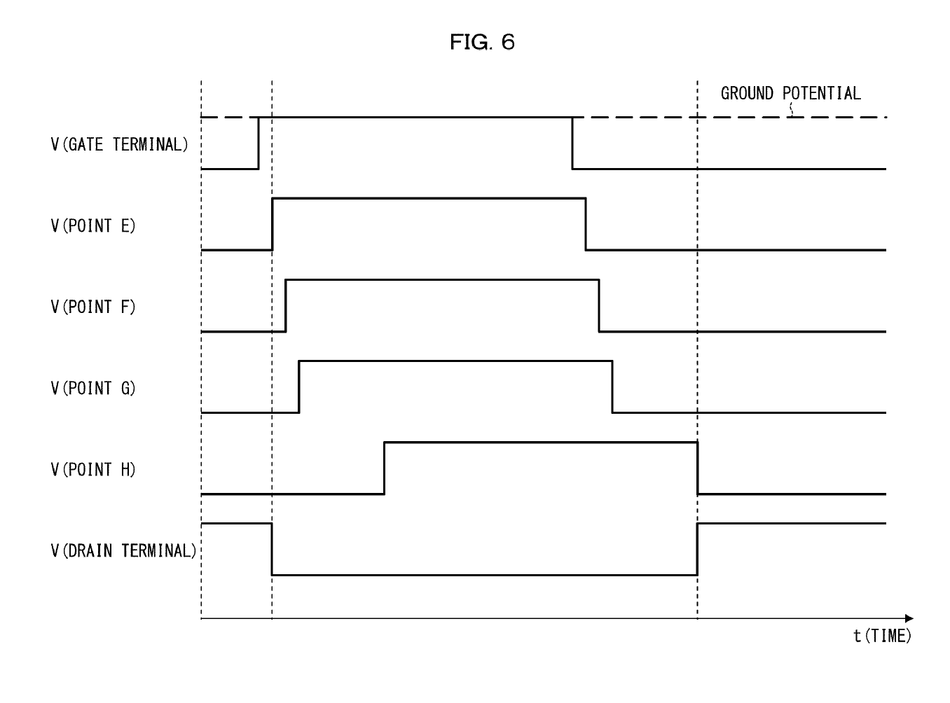

Next, Embodiment 2 of the invention will be described with reference to FIGS. 5 and 6. The present embodiment is different from Embodiment 1 in that a lateral field effect transistor 30 is a normally-on transistor, but otherwise the present embodiment is equivalent to Embodiment 1. For convenience of description, members having the same functions as those of the members illustrated in the figures of Embodiment 1 are denoted by the same reference signs and description thereof will be omitted.

FIG. 5 is a circuit diagram illustrating a schematic configuration of the normally-on lateral field effect transistor 30.

As illustrated in the figure, the normally-on lateral field effect transistor 30 (semiconductor device) includes first to n-th fingers 21, 22, 23 . . . , and 24 that are n (n is an integer equal to or greater than 2) small field effect transistors, a Zener diode 5, a drain terminal 6, a gate terminal 7, a source terminal 8, and wiring resistances (a first wiring resistance 9, a second wiring resistance 10, a third wiring resistance 11 . . . , and an n-th wiring resistance 12).

### Finger

Since the lateral field effect transistor 30 is a normally-on transistor, each of the first to n-th fingers 21, 22, 23 . . . , and 24 is a normally-on small field effect transistor and includes a gate electrode (G), a drain electrode (D), and a source electrode (S).

### Gate Terminal of Normally-On Lateral Field Effect Transistor

The gate terminal 7 of the normally-on lateral field effect transistor 30 is connected to the gate electrodes (G) of the first to n-th fingers 21, 22, 23 . . . , and 24. The first wiring resistance 9 is present in wiring between the gate terminal 7 and the gate electrode (G) of the first finger 21. The first wiring resistance 9 and the second wiring resistance 10 are present in series in wiring between the gate terminal 7 and the gate electrode (G) of the second finger 22. The first wiring resistance 9, the second wiring resistance 10, and the third wiring resistance 11 are present in series in wiring between the gate terminal 7 and the gate electrode (G) of the third finger 23. The first to n-th wiring resistances (the first wiring resistance 9, the second wiring resistance 10, the third wiring resistance 11, . . . , and the n-th wiring resistance 12), that is n wiring resistances, are present in series in wiring between the gate terminal 7 and the gate electrode (G) of the n-th finger 24.

### Drain Terminal and Source Terminal Of Normally-On Lateral Field Effect Transistor

The drain electrodes (D) of the first to n-th fingers 21, 22, 23 . . . , and 24 are connected to the drain terminal 6 of the normally-on lateral field effect transistor 30. On the other hand, the source electrodes (S) of the first to n-th fingers 21, 22, 23 . . . , and 24 are connected to the source terminal 8 of the normally-on lateral field effect transistor 30.

### About Operation of Normally-On Lateral Field Effect Transistor

FIG. 6 illustrates operation timing of the lateral field effect transistor 30 illustrated in FIG. 5.

Each voltage illustrated in FIG. 6 indicates voltage change of each portion of the lateral field effect transistor 30 illustrated in FIG. 5. The voltage of the gate terminal 7 of the lateral field effect transistor 30 is denoted by V (gate terminal), the voltage of a point E in FIG. 5 is denoted by V (point E), the voltage of a point F in FIG. 5 is denoted by V (point F), the voltage of a point G in FIG. 5 is denoted by V (point G), the voltage of a point H in FIG. 5 is denoted by V (point H), and the voltage of the drain terminal 6 of the lateral field effect transistor 30 is denoted by V (drain terminal).

Note that, since the lateral field effect transistor 30 is a normally-on transistor, the lateral field effect transistor 30 is turned on even when V (gate terminal) has ground potential (0 V) and V (gate terminal) needs to have negative potential (negative voltage) in order for the lateral field effect transistor 30 to be turned off.

As illustrated in V (gate terminal), when voltage (ground potential) equal to or greater than a gate voltage at which the lateral field effect transistor 30 is turned on is input to the gate terminal 7, first, voltage (ground potential) equal to or greater than a gate voltage at which the first finger 21 nearest to the gate terminal 7 is turned on is input to the gate electrode (G) of the finger 21 with delay due to influence of the first wiring resistance 9 as illustrated in V (point E). When the first finger 21 is turned on, current flows through the lateral field effect transistor 30, so that the current appears in V (drain terminal) and V (drain terminal) is changed from a high level to a low level at timing when the first finger 21 is turned on. Then, with more delay due to influence of the second wiring resistance 10 being added as illustrated in V (point F), voltage (ground potential) equal to or greater than a gate voltage at which the second finger 22 is turned on is input to the gate electrode (G) of the second finger 22. When the second finger 22 is turned on, current flows through the lateral field effect transistor 30, but since V (drain terminal) has been already changed from the high level to the low level, at timing when the second finger 22 is turned on, there is no change in the voltage of V (drain terminal) and the low level is kept. Then, with more delay due to influence of the second wiring resistance 10 and the third wiring resistance 11 being added as illustrated in V (point G), voltage (ground potential) equal to or greater than a gate voltage at which the third finger 23 is turned on is input to the gate electrode (G) of the third finger 23. When the third finger 23 is turned on, current flows through the lateral field effect transistor 30, but since V (drain terminal) has been already changed from the high level to the low level, at timing when the third finger 23 is turned on, there is no change in the voltage of V (drain terminal) and the low level is kept. Finally, with more delay due to influence of the second to n-th wiring resistances (10, 11 . . . , and 12) being added as illustrated in V (point H), voltage (ground potential) equal to or greater than a gate voltage at which the n-th finger 24 is turned on is input to the gate electrode (G) of the n-th finger 24. When the n-th finger 24 is turned on, current flows through the lateral field effect transistor 30, but since V (drain terminal) has been already changed from the high level to the low level, at timing when the n-th finger 24 is turned on, there is no change in the voltage of V (drain terminal) and the low level is kept.

When voltage (ground potential) equal to or greater than a gate voltage at which the lateral field effect transistor 30 is turned on is input to the gate terminal 7 for a certain time period and the voltage level is then returned to the negative potential (negative voltage) serving as the low level as illustrated in V (gate terminal), the first finger 21 is turned off with delay due to influence of the first wiring resistance 9 as illustrated in V (point E), but the change of the current does not appear in V (drain terminal) because the other fingers 22, 23 . . . , and 24 are on. With a lapse of time, the second finger 22 and the third finger 23 are successively turned off with delay due to influence of the wiring resistance in the same manner, and V (drain terminal) keeps the low level until the n-th finger 24 is turned off and V (drain terminal) is brought into the high level at timing when the n-th finger 24 is turned off.

As illustrated in the figure, in the normally-on lateral field effect transistor 30, an OFF delay time tends to be longer than an ON delay time due to influence of the wiring resistance similarly to the case of the normally-off lateral field effect transistor 20.

The lateral field effect transistor 30 of the present embodiment has a configuration in which the first to n-th fingers 21, 22, 23 . . . , and 24 are arranged closer to the gate terminal 7 than the Zener diode 5. With the configuration, it is possible to suppress an increase in the wiring resistances that are present in series in wiring between the gate terminal 7 and the gate electrode (G) of the n-th finger 24 farthest from the gate terminal 7 and a finger having a markedly high wiring resistance is not generated because of arrangement of the first to n-th fingers 21, 22, 23 . . . , and 24. As a result, in the lateral field effect transistor 30, the OFF delay time is able to be reduced and breakdown of a specific finger is less likely to be generated compared to a conventional one.

### Embodiment 3

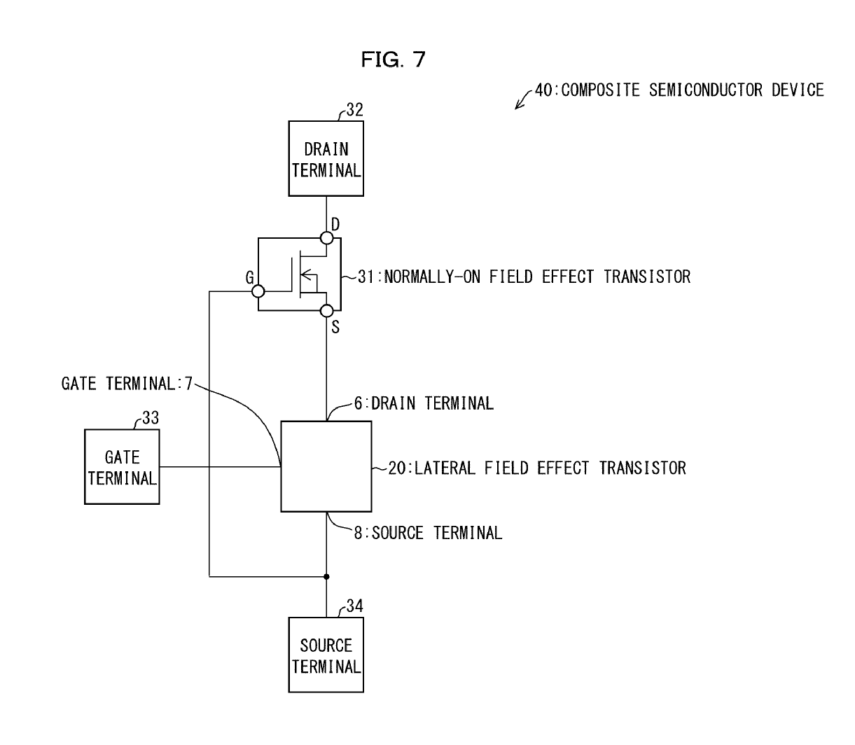

Next, Embodiment 3 of the invention will be described with reference to FIG. 7. The present embodiment is different from Embodiment 1 in that a composite semiconductor device 40 includes the normally-off lateral field effect transistor 20 and a normally-on field effect transistor 31, but otherwise the present embodiment is equivalent to Embodiment 1. For convenience of description, members having the same functions as those of the members illustrated in the figures of Embodiment 1 are denoted by the same reference signs and description thereof will be omitted.

FIG. 7 is a circuit diagram illustrating a schematic configuration of the composite semiconductor device 40.

As illustrated in the figure, the composite semiconductor device 40 includes the normally-off lateral field effect transistor 20, the normally-on field effect transistor 31, a drain terminal 32, a gate terminal 33, and a source terminal 34.

A drain electrode (D) of the normally-on field effect transistor 31 is connected to the drain terminal 32 of the composite semiconductor device 40, a gate electrode (G) of the normally-on field effect transistor 31 is connected to the source terminal 34 of the composite semiconductor device 40, and a source electrode (S) of the normally-on field effect transistor 31 is connected to the drain terminal 6 of the lateral field effect transistor 20.

The gate terminal 7 of the lateral field effect transistor 20 is connected to the gate terminal 33 of the composite semiconductor device 40 and the source terminal 8 of the lateral field effect transistor 20 is connected to the source terminal 34 of the composite semiconductor device 40.

In the composite semiconductor device 40, control of a withstand voltage is performed by the normally-on field effect transistor 31 and control of current is performed by the normally-off field effect transistor, specifically, the normally-off lateral field effect transistor 20, so that the OFF delay time of the lateral field effect transistor 20 is a fundamental factor for deciding an OFF delay time of the composite semiconductor device 40.

Since the lateral field effect transistor 20 has a configuration in which the first to n-th fingers 1, 2, 3 . . . , and 4 are arranged closer to the gate terminal 7 than the Zener diode 5, it is possible to suppress an increase in the wiring resistances that are present in series in wiring between the gate terminal 7 and the gate electrode (G) of the n-th finger 4 farthest from the gate terminal 7. Thus, usage of the lateral field effect transistor 20 capable of reducing the OFF delay time makes it possible to reduce the OFF delay time of the composite semiconductor device 40 compared to a conventional one.

### Embodiment 4

Next, Embodiment 4 of the invention will be described with reference to FIG. 8. The present embodiment is different from Embodiment 3 in that a composite semiconductor device 50 is a packaged composite semiconductor device, but otherwise the present embodiment is equivalent to Embodiment 3. For convenience of description, members having the same functions as those of the members illustrated in the figure of Embodiment 3 are denoted by the same reference signs and description thereof will be omitted.

FIG. 8 illustrates a schematic configuration of the composite semiconductor device 50.

As illustrated in the figure, the normally-off lateral field effect transistor 20 formed on a Si-based substrate and the normally-on field effect transistor 31 formed on an III-N-based substrate such as a GaN-based substrate are die-bonded onto a die pad 41 provided in the composite semiconductor device 50.

A gate electrode (G) of the normally-on field effect transistor 31 and the die pad 41 one end of which is a source terminal 34 of the composite semiconductor device 50 are connected via a first wire 45, the gate terminal 7 of the lateral field effect transistor 20 and a gate terminal 33 of the composite semiconductor device 50 are connected via a second wire 46, the drain terminal 6 of the lateral field effect transistor 20 and the source electrode (S) of the normally-on field effect transistor 31 are connected via a third wire 47, the drain electrode (D) of the normally-on field effect transistor 31 and a drain terminal 32 of the composite semiconductor device 50 are connected via a fourth wire 48, and a source terminal 6 (not-illustrated) of the lateral field effect transistor 20 is connected to an electrode on a back surface of the chip through a trench and thus connected to the die pad 41.

The composite semiconductor device 50 is constituted in such a manner that a part of the three terminals of the drain terminal 32, the gate terminal 33, and the source terminal 34 is sealed with a package 49.

Note that, since current flowing through the normally-on field effect transistor 31 flows through the third wire 47 and the fourth wire 48, a back surface of the normally-on field effect transistor 31 is mainly used to fix the chip and is fixed to the die pad 41 by using a conductive material, but may be fixed to the die pad 41 by using insulating material.

Since the normally-on field effect transistor 31 formed on the III-N-based substrate such as a GaN-based substrate has a lower on-resistance per area than that of the normally-off lateral field effect transistor 20 formed on the Si-based substrate, when the two field effect transistors have the same size, the normally-on field effect transistor 31 is able to cause larger current to flow than the normally-off lateral field effect transistor 20.

In order to enable die bonding both chips of the normally-on field effect transistor 31 and the normally-off lateral field effect transistor 20 onto the die pad 41 and causing large current to flow through the normally-off lateral field effect transistor 20 formed on the Si-based substrate while keeping a space for wire formation, it is most efficient in terms of the area to form the both chips in a rectangular shape as illustrated in FIG. 8.

Since the composite semiconductor device 50 includes the normally-on field effect transistor 31 and the normally-off lateral field effect transistor 20 which are in the rectangular shape, the composite semiconductor device 50 is able to cause large current to flow through the normally-off lateral field effect transistor 20 and achieves efficient arrangement in terms of the area. Since the composite semiconductor device 50 has the Zener diode 5 incorporated in the normally-off lateral field effect transistor 20, when voltage larger than or equal to withstand voltage of the normally-off lateral field effect transistor 20 is applied to the normally-off lateral field effect transistor 20, breakdown is able to be prevented. Since the Zener diode 5 receives small influences of the wiring resistance, the Zener diode 5 is arranged farthest from the gate terminal 7 in the lateral field effect transistor 20. With such arrangement, the first to n-th fingers 1, 2, 3 . . . , and 4 that are greatly influenced by the wiring resistances are able to be arranged closer to the gate terminal 7 as much as possible. Because of including such a lateral field effect transistor 20, the composite semiconductor device 50 is also able to reduce the OFF delay time.

Though description has been given in the present embodiment by taking a case where the gate electrode (G), the drain electrode (D), and the source electrode (S) of the normally-on field effect transistor 31 are formed on the same surface as an example, there is no limitation thereto, and, for example, the gate electrode (G) and the drain electrode (D) of the normally-on field effect transistor 31 may be formed on the same surface (upper surface) and the source electrode (S) of the normally-on field effect transistor 31 may be formed on a back surface (lower surface) of the aforementioned same surface. In this case, it is preferable that the gate terminal 7 and the source terminal 8 of the normally-off lateral field effect transistor 20 are formed on the same surface (upper surface) and the drain terminal 6 is formed on the back surface (lower surface) of the aforementioned same surface.

Note that, when the composite semiconductor device 40 requires a high withstand voltage, the normally-on field effect transistor 31 included in the composite semiconductor device 40 requires a high withstand voltage and a low on-resistance, so that the normally-on field effect transistor 31 tends to have a large size.

The normally-off lateral field effect transistor 20 needs the drain electrode (D) having a large area for making connection to the source electrode (S) of the normally-on field effect transistor 31 and requires a high threshold voltage and a low on-resistance in order to prevent an erroneous operation.

### Conclusion

A semiconductor device in an aspect 1 of the invention is a semiconductor device that includes a plurality of normally-off or normally-on field effect transistors, a gate terminal, a drain terminal, and a source terminal. Each of the field effect transistors has a gate electrode connected to the gate terminal, a drain electrode connected to the drain terminal, and a source electrode connected to the source terminal. A Zener diode that has an anode electrode connected to the source terminal and a cathode electrode connected to the drain terminal is also included. The field effect transistors are each arranged to have a distance from the gate terminal increasing in order and form a block, and the block is arranged closer to the gate terminal than the Zener diode.

According to the aforementioned configuration, the plurality of field effect transistors that are greatly influenced by a wiring resistance are arranged closer to the gate terminal than the Zener diode. Thus, it is possible to suppress delay of transmission, to the gate electrode of each of the field effect transistors, of a signal supplied from the gate terminal and realize a semiconductor device in which response performance is improved.

In the semiconductor device in an aspect 2 of the invention, it is preferable that the Zener diode is provided at one end, the gate terminal is provided at the other end opposite the one end, and a length between the Zener diode and the gate terminal in a first direction is longer than a length in a second direction orthogonal to the first direction.

According to the aforementioned configuration, it is possible to realize a lateral semiconductor device in which the first direction is longer than the second direction, that is, a rectangular semiconductor device, and to cause large current to flow through the semiconductor device.

In the semiconductor device in an aspect 3 of the invention, it is preferable that each of the field effect transistors is a normally-off field effect transistor, the gate terminal and any one of the drain terminal and the source terminal are formed on a first same surface, and the other of the drain terminal and the source terminal is formed on a back surface of the first same surface.

According to the aforementioned configuration, since any one of the drain terminal and the source terminal is formed on the back surface of the surface on which the gate terminal is formed, combination with an electric field effect transistor in which any one of a drain terminal (drain electrode) and a source terminal (source electrode) is provided on a back side is easily achieved.

It is preferable that a composite semiconductor device in an aspect 4 of the invention includes: the semiconductor device according to the aspect 3; a normally-on field effect transistor that has a gate electrode, a drain electrode, and a source electrode; a second gate terminal; a second drain terminal; and a second source terminal. The second drain terminal is connected to the drain electrode of the normally-on field effect transistor, the second source terminal is connected to the gate electrode of the normally-on field effect transistor and the source terminal of the semiconductor device, the second gate terminal is connected to the gate terminal of the semiconductor device, and the source electrode of the normally-on field effect transistor is connected to the drain terminal of the semiconductor device.

According to the aforementioned configuration, since the semiconductor device capable of reducing an OFF delay time compared to a conventional one is used, it is possible to reduce the OFF delay time of the composite semiconductor device.

In the composite semiconductor device in an aspect 5 of the invention, the normally-on field effect transistor may include a semiconductor layer made of GaN or SiC.

According to the aforementioned configuration, since it is possible to realize the normally-on field effect transistor having a low on-resistance per area, it is possible to cause larger current to flow.

In the composite semiconductor device in an aspect 6 of the invention, the gate electrode, the drain electrode, and the source electrode of the normally-on field effect transistor may be formed on a second same surface.

According to the aforementioned configuration, a back surface of the second same surface of the normally-on field effect transistor is able to be used for fixation.

In the composite semiconductor device in an aspect 7 of the invention, it is preferable that the gate electrode and the drain electrode of the normally-on field effect transistor are formed on a second same surface, the source electrode of the normally-on field effect transistor is formed on a back surface of the second same surface, the gate terminal and the source terminal of the semiconductor device are formed on the first same surface, the drain terminal of the semiconductor device is formed on a back surface of the first same surface, the first same surface and the second same surface are upper surfaces, and the back surface of the first same surface and the back surface of the second same surface are lower surfaces.

According to the aforementioned configuration, it is possible to easily combine the normally-on field effect transistor having the source electrode formed on the lower surface and the semiconductor device having the drain terminal formed on the lower surface.

In the composite semiconductor device in an aspect 8 of the invention, it is preferable that the normally-on field effect transistor has a rectangular shape.

According to the aforementioned configuration, it is possible to achieve efficient arrangement in terms of the area.

In the composite semiconductor device in an aspect 9 of the invention, it is preferable that a portion other than a part of the second gate terminal, a part of the second drain terminal, and a part of the second source terminal is sealed.

According to the aforementioned configuration, it is possible to realize the composite semiconductor device that is sealed.

Note that, the invention is not limited to the embodiments described above, and may be modified in various manners within the scope of the claims, and an embodiment achieved by appropriately combining technical means disclosed in different embodiments is also encompassed in the technical scope of the invention.

### INDUSTRIAL APPLICABILITY

The invention is able to be suitably used for a semiconductor device or a composite semiconductor device.

### REFERENCE SIGNS LIST

1 first finger (field effect transistor)
2 second finger (field effect transistor)
3 third finger (field effect transistor)
4 n-th finger (field effect transistor)
5 Zener diode
6 drain terminal
7 gate terminal
8 source terminal
9 first wiring resistance
10 second wiring resistance
11 third wiring resistance
12 n-th wiring resistance
13 pulse generator
14 terminating resistance
15 load resistance
16 power source
17 block
20 lateral field effect transistor (semiconductor device)
21 first finger (field effect transistor)
22 second finger (field effect transistor)
23 third finger (field effect transistor)
24 n-th finger (field effect transistor)
30 lateral field effect transistor (semiconductor device)
31 normally-on field effect transistor
32 drain terminal
33 gate terminal
34 source terminal
40 composite semiconductor device
41 die pad
45 first wire
46 second wire
47 third wire
48 fourth wire
49 package
50 composite semiconductor device
A anode electrode
C cathode electrode

1. A semiconductor device comprising:
a plurality of normally-off or normally-on field effect transistors;
a gate terminal;
a drain terminal;
a source terminal;
each of the field effect transistors having a gate electrode connected to the gate terminal, a drain electrode connected to the drain terminal, and a source electrode connected to the source terminal; and
a Zener diode that has an anode electrode connected to the source terminal and a cathode electrode connected to the drain terminal, wherein
the field effect transistors are each arranged to have a distance from the gate terminal increasing in order and form a block, and
the block is arranged closer to the gate terminal than the Zener diode.

2. The semiconductor device according to claim 1, wherein
the Zener diode is provided at one end,
the gate terminal is provided at the other end opposite the one end, and
a length between the Zener diode and the gate terminal in a first direction is longer than a length in a second direction orthogonal to the first direction.

3. The semiconductor device according to claim 1, wherein
each of the field effect transistors is a normally-off field effect transistor,
the gate terminal and any one of the drain terminal and the source terminal are formed on a first same surface, and
the other of the drain terminal and the source terminal is formed on a back surface of the first same surface.

4. A composite semiconductor device, comprising:
the semiconductor device according to claim 3;
a normally-on field effect transistor that has a gate electrode, a drain electrode, and a source electrode;
a second gate terminal;
a second drain terminal; and
a second source terminal, wherein
the second drain terminal is connected to the drain electrode of the normally-on field effect transistor, the second source terminal is connected to the gate electrode of the normally-on field effect transistor and the source terminal of the semiconductor device, the second gate terminal is connected to the gate terminal of the semiconductor device, and the source electrode of the normally-on field effect transistor is connected to the drain terminal of the semiconductor device.

5. The composite semiconductor device according to claim 4, wherein the normally-on field effect transistor includes a semiconductor layer made of GaN or SiC.
